(19) United States
(12) Patent Application Publication
(10) Pub. No.: US 2025/0212616 A1
(43) Pub. Date: Jun. 26, 2025

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Ruiping LI, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/852,480

(22) PCT Filed: Jun. 30, 2023
(86) PCT No.: PCT/CN2023/104760

§ 371 Date: Sep. 29, 2024

(30) Foreign Application Priority Data
Nov. 22, 2022 (CN) 202211468130.9

(51) Int. Cl. H10K 59/122; H10K 59/40

(52) U.S. Cl. CPC H10K 59/122; H10K 59/40

(57) ABSTRACT

The present invention embodiment provides a display panel and a display device, including an array substrate, a first electrode layer, a second electrode layer, a pixel definition layer, and a light emitting layer. The first electrode layer includes a first electrode and a second electrode. The first electrode includes a first recess structure. Light inside the display panel can act multiple times through the recess structure between the first electrode and the second electrode, so that the first display region and the second display region have consistent brightness attenuation, thereby improving the consistency of the display effect in different regions.

### FIELD OF INVENTION

The present invention relates to fields of display panel and device manufacturing, especially to a display panel and display device.

### BACKGROUND OF INVENTION

With the continuous development of display panel manufacturing technology, there are increasing demands of various performances of display panels and devices.

Display panels produced using conventional technology, in addition to being capable of normally displaying images, also possess many other functions. For example, in existing display panels and devices, a light-transmitting region is typically provided, and a sensor is placed at a corresponding position within the light-transmitting region. The sensor within the light-transmitting region receives ambient light and performs imaging to realize a camera function. To achieve a full screen display effect in conventional technology, the light-transmitting region is not perforated, and typically, no touch-related metal wirings are placed when setting up the light-transmitting region. Because the light-transmitting region and the normal display region use different structures, when the screen is illuminated under conditions of wide-angle observation without light blockage, the brightness attenuation within the light-transmitting region is much slower compared to the brightness attenuation within the normal display region. This results in a significant difference in brightness and display quality between the light-transmitting region and the display region. When the user is using the device, two different display effects appear in the different display regions of the entire display screen, thereby reducing the user's experience.

Therefore, there is a need to propose a solution to the issues present in conventional technology.

### SUMMARY OF INVENTION

As described above, in the full screen display panel prepared using conventional technology, the attenuation of display brightness in the light-transmitting region is less than the attenuation of display brightness in the normal display region. This results in two different display effects on the panel, which is not conducive to further improving the overall performance of the display panel.

To solve the above issue, the present invention embodiment provides a display panel and a display device to effectively mitigate an issue of inconsistent display brightness in different display regions in the conventional full screen display panel, and a poor display effect and to effectively improve a comprehensive performance of the display panel.

To solve the above technical issue, the present invention provides a display panel, the display panel comprises a first display region and a second display region, wherein a light transmittance of the first display region is greater than a light transmittance of the second display region, and the display panel comprises:
an array substrate;
a first electrode layer disposed on a side of the array substrate, wherein the first electrode layer comprises a plurality of first electrodes disposed in the first display region and a plurality of second electrodes disposed in the second display region;
a pixel definition layer disposed on a side of the first electrode layer away from the array substrate, wherein the pixel definition layer comprises a plurality of pixel apertures, and the pixel apertures are disposed to correspond to the first electrodes or the second electrodes;
a light emitting layer disposed on a side of the pixel definition layer away from the array substrate; and
a second electrode layer disposed on a side of the light emitting layer away from the array substrate;
wherein the first electrodes comprises a first recess structure; in the first display region and the second display region, a light transmittance of the first display region is greater than a light transmittance of the second display region, and the display panel comprises:
an array substrate;
a first electrode layer disposed on a side of the array substrate, wherein the first electrode layer comprises a plurality of first electrodes disposed in the first display region and a plurality of second electrodes disposed in the second display region;
a pixel definition layer disposed on a side of the first electrode layer away from the array substrate, wherein the pixel definition layer comprises a plurality of pixel apertures, and the pixel apertures are disposed to correspond to the first electrodes or the second electrodes;
a light emitting layer disposed on a side of the pixel definition layer away from the array substrate; and
a second electrode layer disposed on a side of the light emitting layer away from the array substrate;
wherein the first electrodes comprises a first recess structure.

According to an embodiment of the present invention, the display panel further comprises:
a touch layer disposed on a side of the second electrode layer away from the array substrate, wherein the touch layer comprises a first aperture disposed to correspond to the first display region;
the second electrode comprises a second recess structure, and a size of at least a part of the second recess structure is different from a size of at least a part of the first recess structure.

According to an embodiment of the present invention, a first included angle is defined between a plane corresponding to a bottom portion of the first recess structure and a sidewall of the first recess structure, a second included angle is defined between a plane corresponding to a bottom portion of the second recess structure and a sidewall of the second recess structure, and each of the first included angle and the second included angle is less or equal to 90°;
the first recess structure comprises a first height, and the second recess structure comprises a second height;
the bottom portion of the first recess structure comprises a first width, the bottom portion of the second recess structure comprises a second width; in three correspondence relations formed by the first width to the second width, the first included angle to the second included angle, and the first height to the second height, and parameter values in at least one of the correspondence relations are not the same.

According to an embodiment of the present invention, the first width is the same as the second width; and
the first width is set to 1 um to 5 um.

According to an embodiment of the present invention, the first height is greater than or equal to the second height, and/or, the first included angle is greater than or equal to the second included angle.

According to an embodiment of the present invention, the first width is less than the second width, the first height is greater than the second height, and/or, the first included angle is equal to the second included angle.

According to an embodiment of the present invention, the first included angle is set to 20° to 60°, and the second included angle is set to 0° to 60°.

According to an embodiment of the present invention, a quantity of the first recess structure is greater than a quantity of the second recess structure.

According to a second aspect of the present invention embodiment, a display panel is also provided, the display panel comprising: a first display region and a second display region, wherein a light transmittance of the first display region is greater than a light transmittance of the second display region, and the display panel comprises:
an array substrate;
a first electrode layer disposed on a side of the array substrate, wherein the first electrode layer comprises a plurality of first electrodes disposed in the first display region and a plurality of second electrodes disposed in the second display region;
a pixel definition layer disposed on a side of the first electrode layer away from the array substrate, wherein the pixel definition layer comprises a plurality of pixel apertures, and the pixel apertures are disposed to correspond to the first electrodes or the second electrodes;
a light emitting layer disposed on a side of the pixel definition layer away from the array substrate; and
a second electrode layer disposed on a side of the light emitting layer away from the array substrate;
wherein the first electrodes comprises a first recess structure.

According to an embodiment of the present invention, the display panel further comprises:
a touch layer disposed on a side of the second electrode layer away from the array substrate, wherein the touch layer comprises a first aperture disposed to correspond to the first display region;
the second electrode comprises a second recess structure, and a size of at least a part of the second recess structure is different from a size of at least a part of the first recess structure.

According to an embodiment of the present invention, a first included angle is defined between a plane corresponding to a bottom portion of the first recess structure and a sidewall of the first recess structure, a second included angle is defined between a plane corresponding to a bottom portion of the second recess structure and a sidewall of the second recess structure, and each of the first included angle and the second included angle is less or equal to 90°;
the first recess structure comprises a first height, and the second recess structure comprises a second height;
the bottom portion of the first recess structure comprises a first width, the bottom portion of the second recess structure comprises a second width; in three correspondence relations formed by the first width to the second width, the first included angle to the second included angle, and the first height to the second height, and parameter values in at least one of the correspondence relations are not the same.

According to an embodiment of the present invention, the first width is the same as the second width; and
the first width is set to 1 um to 5 um.

According to an embodiment of the present invention, the first height is greater than or equal to the second height, and/or, the first included angle is greater than or equal to the second included angle.

According to an embodiment of the present invention, the first width is less than the second width, the first height is greater than the second height, and/or, the first included angle is equal to the second included angle.

According to an embodiment of the present invention, the first included angle is set to 20° to 60°, and the second included angle is set to 0° to 60°.

According to an embodiment of the present invention, a quantity of the first recess structure is greater than a quantity of the second recess structure.

According to an embodiment of the present invention, the first recess structure is arranged symmetrically relative to a central axis line of a corresponding one of the pixel apertures, and the recess structure is arranged symmetrically relative to the central axis line of a corresponding one of the pixel apertures.

According to an embodiment of the present invention, the display panel further comprises:
a planarization layer disposed between the array substrate and the first electrode layer, wherein the planarization layer comprises: a third recess structure disposed to correspond to the first recess structure and a fourth recess structure disposed to correspond to the second recess structure, and a depth of each of the third recess structure of the fourth recess structure is less than or equal to a thickness of the planarization layer.

According to an embodiment of the present invention, an area of the first electrode is less than an area of the second electrode, and a quantity of the first electrodes in a unit area is equal to a quantity of the second electrodes;
or
an area of the first electrode is greater than an area of the second electrode, and a quantity of the first electrodes in a unit area is less than a quantity of the second electrodes.

According to a third aspect of the present invention embodiment, the present application also provides a display device, the display device comprises a display panel, and a display region and a light transmitting region of the display panel have consistent display brightness.

### Beneficial Effect

As described above, beneficial effects of the present invention embodiment are as follows:

The present invention embodiment provides a display panel and a display device. The display panel comprises an array substrate, a first electrode layer, a second electrode layer, a pixel definition layer, and a light emitting layer. The first electrode layer comprises a first electrode disposed in a first display region and a second electrode disposed in a second display region. The first electrode comprises a first recess structure. When the display panel displays normally, light in the display panel can be affected by recess structures corresponding to the first electrode and the second electrode on multiple times such that the first display region and the second display region have consistent brightness attenuation, thereby efficiently improving consistency of display effects in different regions of the display panel.

### DESCRIPTION OF DRAWINGS

FIG. 1A is a schematic structural view of a display panel provided by an embodiment of the present application;

FIG. 1B is a schematic view of brightness variation of a conventional display panel observed at different viewing angles;

FIG. 2A is a schematic structural view of film layers of the display panel provided by the embodiment of the present application;

FIG. 2B is a schematic structural view of film layers of another display panel provided by the embodiment of the present application;

FIG. 3 is a schematic view of a first recess structure and a second recess structure provided by the embodiment of the present application;

FIG. 4 is a simplified schematic view of the second recess structure provided by the embodiment of the present application;

FIG. 5 is a simplified schematic view of a third recess structure provided by the embodiment of the present application;

FIG. 6 is a schematic structural view of film layers corresponding to a first display region in the display panel provided by the embodiment of the present application; and

FIG. 7 is a schematic structural view of film layers of another display panel provided by the embodiment of the present application.

### DETAILED DESCRIPTION OF PREFERRED EMBODIMENTS

The descriptions of the following embodiments are provided with reference to the accompanying drawings to illustrate specific embodiments that can be implemented according to the present disclosure.

With the continuous development of display apparatus and device manufacturing technologies, higher demands have been placed on the performance and display effect of display panels.

A full screen display panel can display normally over the entire screen area. However, with the diversification of functions for display panels, it is often necessary to set up a light-transmitting region on the display panel, and to place a photosensitive module within this light-transmitting region to enable the camera function of the display panel. The structure within the light-transmitting region is different from the structure within the display region, which results in inconsistent brightness attenuation between the light-transmitting region and the display region, thereby affecting the display effect.

The embodiment of the present application provides a display panel and a display device to effectively improve the issue of inconsistent display brightness and brightness attenuation within the light transmitting region in conventional full-screen display panels.

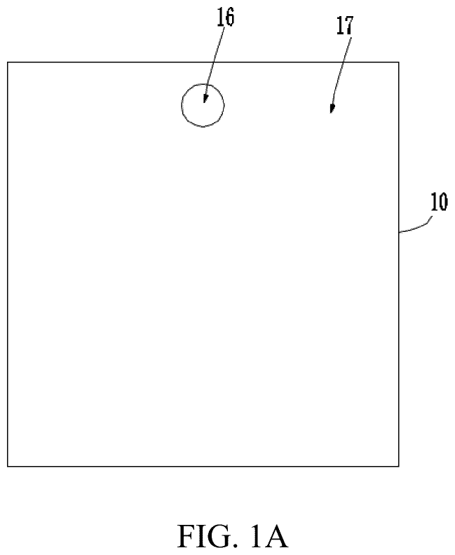

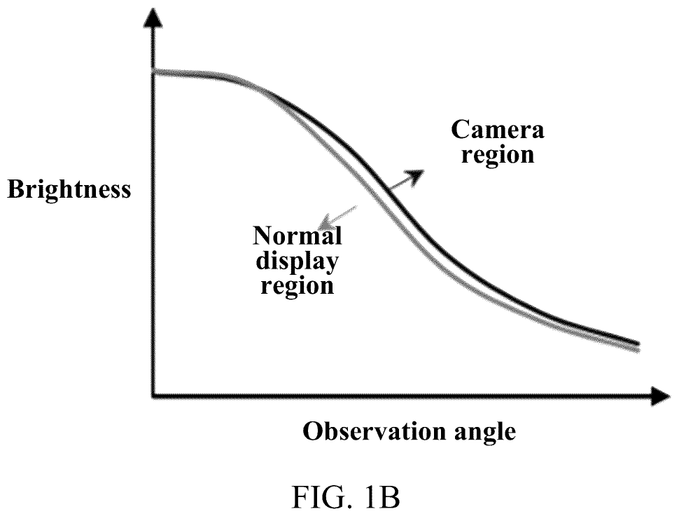

With reference to FIG. 1A, FIG. 1A is a schematic structural view of a display panel provided by an embodiment of the present application. The display panel comprises a first display region 16 and a second display region 17. In particular, the second display region 17 can be disposed on at least one side of the first display region 16, for example, the first display region 16 can be disposed in an edge region of the display panel 10, or the first display region 16 is disposed at a middle location of the display screen. In the embodiment of the present application, the second display region 17 is disposed to surround the first display region 16, the first display region 16 is a camera region, and the second display region 17 is a normally light emitting display region, which will be used as an example for explanation.

Also, the embodiment of the present application, a light transmittance of the first display region 16 is greater than a light transmittance of the second display region 17, thereby achieving a better camera effect. In the embodiment of the present application, when the display panel 10 displays normally, both the first display region 16 and the second display region 17 can display normally, and display brightness in the first display region 16 and the second display region 17 comprise consistent attenuation. With reference to FIG. 1B, FIG. 1B is a schematic view of brightness variation of a conventional display panel observed at different viewing angles. The display panel manufactured by the conventional technology, when observed at different angles, for example, a light transmitting region and a display region observed at different angles, an attenuation extent of brightness of the light transmitting region is different from an attenuation extent of brightness in the display region. Namely, two curves at different angles in the chart cannot completely coincide with each other, thereby resulting in uneven brightness between the light transmitting region and the display region. In the embodiment of the present application provides a display panel. When a user observes the display panel from different angles, such as at a large viewing angle or a small viewing angle, the display effect of the light transmitting region and the display region is indistinguishable. The brightness attenuation curves corresponding to both regions have better consistency, thereby achieving a full-screen display effect.

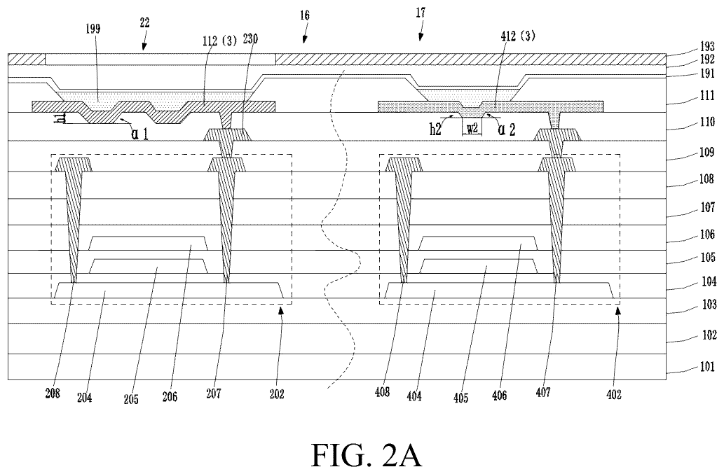

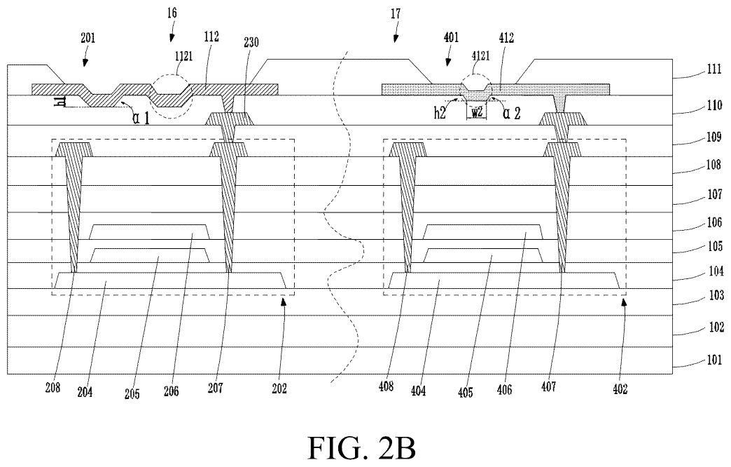

With reference to FIGS. 2A to 2B, FIG. 2A is a schematic structural view of film layers of the display panel provided by the embodiment of the present application; FIG. 2B is a schematic structural view of film layers of another display panel provided by the embodiment of the present application. In combination with the structure of the display panel in FIG. 1A, in the embodiment of the present application, the display panel comprises an array substrate, and the array substrate is mainly a thin film transistor array substrate. The array substrate comprises an underlay substrate 101, a first buffer layer 102, a second buffer layer 103, a first insulation layer 104, a second insulation layer 105, a first medium layer 106, a third insulation layer 107, a second medium layer 108.

Furthermore, in the embodiment of the present application, a plurality of thin film transistors are correspondingly disposed on the array substrate. in the following embodiment, a first thin film transistor 202 and a second thin film transistor 402 are used as an example for explanation. The first thin film transistor 202 is disposed in in the first display region 16, and the second thin film transistor 402 is disposed the second display region 17. Also, each thin film transistor comprises a gate electrode, an active layer, and a source/drain metal layer. Also, in the following embodiment, both two thin film transistors use a dual-gate electrode thin film transistor as an example for explanation. For a specific product, the thin film transistor can also be set as a single gate electrode thin film transistor. Also, a top gate or bottom gate thin film transistor is suitable for the display panel in the embodiment of the present application.

The first thin film transistor 202 comprises a first active layer 204, a first gate electrode 205, a second gate electrode 206, a first source electrode 208, and a first drain electrode 207. The second thin film transistor 402 comprises a second active layer 404, a third gate electrode 405, a fourth gate electrode 406, a second source electrode 408, and a second drain electrode 407.

In particular, when each film layer is disposed on the array substrate, the underlay substrate 101 can be set as a flexible underlay substrate or a rigid underlay substrate, for example, a glass underlay substrate, thereby supporting the array substrate. Also, the first buffer layer 102 is disposed on the underlay substrate 101, and the second buffer layer 103 is disposed on the first buffer layer 102. In the embodiment of the present application, thicknesses of the first buffer layer 102 and the second buffer layer 103 can be set the same, or the thickness of the first buffer layer 102 is greater than the thickness of the second buffer layer 103. Also, buffer layers in a specific quantity or thickness can be set to fulfill the demands of different types of products.

Also, the first insulation layer 104 is disposed on the second buffer layer 103. The first active layer 204 and the second active layer 404 are disposed on the second buffer layer 103 in the same layer and are completely covered by the first insulation layer 104. The second insulation layer 105 is disposed on the first insulation layer 104, and the first gate electrode 205 and the third gate electrode 405 are disposed on the first insulation layer 104 and are completely covered by the second insulation layer 105. Furthermore, the first medium layer 106 is disposed on the second insulation layer 105. Also, the second gate electrode 206 and the fourth gate electrode 406 are disposed on the second insulation layer 105 and are completely covered by the first medium layer 106.

Furthermore, the third insulation layer 107 is disposed on the first medium layer 106, and the second medium layer 108 is disposed on the first medium layer 106. Also, the first source electrode 208 and the first drain electrode 207 are disposed on the second medium layer 108, the second source electrode 408 and the second drain electrode 407 are disposed on the second medium layer 108. Also, the first source electrode 208 and the first drain electrode 207 are electrically connected to the first active layer 204 through corresponding via hole structures to finally form the first thin film transistor 202. The second source electrode 408 and the second drain electrode 407 are also electrically connected to the second active layer 404 through another corresponding via holes to finally form the second thin film transistor 402.

In particular, in the embodiment of the present application, each functional layer in the first thin film transistor can be set in the same layer as each functional layer in the second thin film transistor 402, such as placing the gate electrode in the same layer as the gate electrode, and the active layer in the same layer as the active layer. Alternatively, depending on the structure of the actual product, the gate electrode in the first thin film transistor and the gate electrode in the second thin film transistor can be separately placed on different film layers to meet the usage requirements of different products. This will not be elaborated further here.

Furthermore, the display panel further comprises a planarization layer and a pixel definition layer 111. The planarization layer is disposed on the array substrate. In the following embodiment, the planarization layer uses a first planarization layer 109 and a second planarization layer 110 as an example for explanation.

The first planarization layer 109 is disposed on the second medium layer 108, and the first planarization layer 109 completely covers the source/drain metal layer of the first thin film transistor and the second thin film transistor.

In the embodiment of the present application, the pixel definition layer 111 is disposed on the second planarization layer 110, and the pixel definition layer 111 further comprises a pixel aperture defined in a pattern. In particular, in the first display region 16, a first pixel aperture 201 is defined in the pixel definition layer 111. In the second display region 17, a second pixel aperture 401 is defined in the pixel definition layer 111.

Also, the display panel in the embodiment of the present application further comprises a first electrode layer 3. In particular, the first electrode layer 3 is disposed on the second planarization layer 110. The pixel definition layer 111 covers a part of the first electrode layer 3, and the first electrode layer 3 is correspondingly disposed in a pixel aperture region.

Furthermore, the display panel in the embodiment of the present application further comprises a light emitting layer 199, a second electrode layer 191, an encapsulation layer 192, and a touch layer 193. The light emitting layer 199 is disposed on the first electrode layer 3 and is correspondingly disposed in the pixel aperture region. Also, the second electrode layer 191 is disposed on a side of the pixel definition layer 111 away from the array substrate. Also, the second electrode layer 191 is disposed on the pixel definition layer 111 and is electrically connected to the light emitting layer 199. In the embodiment of the present application, the second electrode layer 191 can be an anode layer cooperating with an anode to affect the light emitting layer, there by implementing driving and controlling the light emitting layer 199.

Furthermore, the encapsulation layer 192 is disposed on the second electrode layer 191 to seal each film layer. In the embodiment of the present application, a touch layer 193 is further disposed on the encapsulation layer 192. A first aperture 22 is defined in the touch layer 193 in the first display region 16. The first aperture 22 can be disposed to correspond to the aperture of the pixel definition layer, thereby defining an aperture in the touch layer of the first display region 16 to improve the light transmittance.

In the embodiment of the present application, the first electrode layer serves as the anode of the display panel, providing a control signal to the light-emitting layer through the anode. Additionally, the first electrode layer 3 comprises a first electrode 112 and a second electrode 412, which will be explained as examples.

In particular, the first electrode 112 is correspondingly disposed in the first display region 16, and the second electrode 412 is correspondingly disposed in the second display region 17. The first electrode 112 is disposed on the second planarization layer 110 corresponding to the first pixel aperture 201, and the second electrode 412 is disposed on the second planarization layer 110 corresponding to the second pixel aperture 401.

With reference to FIG. 2B, in the embodiment of the present application, a patterned structure of the first electrode 112 is at least partially different from a patterned structure of the second electrode 412. In particular, a surface structure of the first electrode 112 and a surface structure of the second electrode 412 are set to be different. Also, the surface structure of the first electrode 112 comprises a plurality of recess structures, thereby changing light in the region by different patterned structures. In the embodiment of the present application, the surface structure of the first electrode 112 is a surface facing a light exiting side of the display panel. When the display panel normally emits light and displays, the patterned electrode with different patterned structures can have different effects on the light. In the embodiment of the present application, through the above different electrode structures, the light attenuation effect within the first display region 16 is made consistent with the light attenuation effect within the second display region 17, thereby ensuring the light-emitting display effect of the display panel.

In particular, during disposing the first electrode 112 and the second electrode 412, the surface structures of the first electrode 112 and the second electrode 412 correspond to the recess structures, which can be configured as recessed microstructures, trapezoidal recessed structures, etc. In the first embodiment of the present application, the first electrode 112 and the second electrode 412 are described with trapezoidal recess structures as an example. By using different shapes of recess structures to enhance the light effect in two different regions, the light extraction rate in the first display region is effectively improved, ensuring a full-screen display effect. Additionally, when configuring the second electrode 412 in the second display region, the second electrode 412 can either be positioned near the first display region or be configured as the structure of the second electrode throughout the entire second display region. In the following embodiment, the same second electrode is used throughout the entire second display region as an example.

Also, to ensure the effectiveness of each patterned structure, during installation, the recess structures within the first display region 16 and the second display region 17 are symmetrically arranged with respect to the central axis line of the corresponding pixel apertures. This ensures that light emitted from each region has better consistency.

With reference to FIG. 2B, the first electrode 112 comprises at least one first recess structure 1121, and the second electrode 412 comprises at least one second recess structure 4121. A size of the first recess structure 1121 at least partially different from a size of the second recess structure 4121, and a quantity of the first recess structure 1121 is greater than a quantity of the second recess structure 4121.

With reference to the film layer structure in FIG. 2B, in the first display region 16, recess structure is correspondingly disposed on the second planarization layer 110, and the recess structure corresponds to the first recess structure 1121. For example, a third recess and a fourth recess are defined in the second planarization layer 110, and the first recess structure 1121 is correspondingly disposed in the third recess, and the second recess structure 4121 is correspondingly disposed in the fourth recess. Also, a depth of each of the third recess and the fourth recess is less than or equal to a thickness of the planarization layer.

Therefore, a first included angle al is defined between a plane corresponding to a bottom portion of the first recess structure 1121 and a sidewall of the first recess structure 1121. Similarly, a second included angle α2 is defined between a plane corresponding to a bottom portion of the second recess structure 4121 and a sidewall of the second recess structure 4121. The first included angle and the second included angle are less than or equal to 90°. Namely, the included angle formed between the sidewall and the bottom plane is smaller.

Also, a first height from the bottom portion of the first recess structure 1121 to a top surface of the first recess structure 1121 is h1. A second height from the bottom portion to the top surface of the second recess structure 4121 is h2. A first width of the bottom portion of the first recess structure 1121 is W1, and a second width of the bottom portion of the second recess structure 4121 is W2, as shown in FIG. 2A.

In the embodiment of the present application, by setting the above parameters corresponding to the first recess structure 1121 and the second recess structure 4121, the light in different regions can be directed outward as much as possible, while ensuring that the first display region 16 and the second display region 17 have a good consistent display effect.

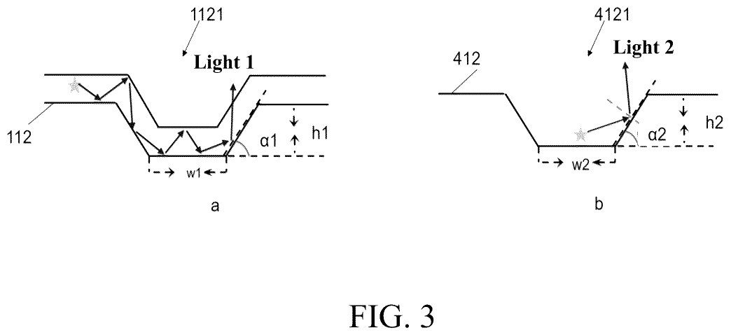

In particular, with reference to FIG. 3, FIG. 3 is a schematic view of a first recess structure 1121 and a second recess structure 4121 provided by the embodiment of the present application. In particular, the section a of FIG. 3 is is a simplified schematic view of the film layer structure in the light transmitting region, and the section b in FIG. 3 is a simplified schematic view of the film layer structure in the normally second display region 17.

In the section a, the lower contour line represents the top surface of the first electrode corresponding to the first recess structure 1121, while the upper contour line represents other film layers on the first electrode, such as the light-emitting layer 199. After the light-emitting layer 199 emits light, the light will be affected by the first recess structure 1121. Similarly, in the section b, the contour line represents the top surface of the second electrode corresponding to the second recess structure 4121.

When the display panel normally emits light and displays, the light inside the display panel is affected by different pattern electrodes in the first display region 16 and the second display region 17. For example, the light 1 in the first display region 16 and the light 2 in the second display region 17 form different light propagation path effects. Light 1 and light 2 pass through different recess structures, such as the effects of the bottom portion and the sidewall of the recess structure. In one aspect, part of the waveguide mode light can be extracted through the bottom portion of the recess structure, thereby improving the light extraction efficiency of the display device. In another aspect, the sidewall of the recess structure can redistribute the internal light of the device, changing the angle of light emission, thereby altering the brightness distribution at different viewing angles of the device, and allowing more light to emit from the pixel aperture. This makes the light-emitting brightness in different regions consistent and improves the display effect.

In the embodiment of the present application, improvements are made to the different structural parameters of the first recess structure 1121 and the second recess structure 4121 to enhance the effect of light.

In particular, in each of the above correspondence relations, for example, in the above threes sets of correspondence relations including a first height h1 of the first recess structure 1121 to a second height h2 of the second recess structure 4121, a first width W1 to a second width W2, and the first included angle α1 to the second included angle α2, parameter values in at least one of correspondence relations are different. For example, the first height h1 is different from the second height h2.

In particular, the first height h1 of the first recess structure 1121 is greater than is equal to the second height h2 of the second recess structure 4121, the first included angle α1 of the first recess structure 1121 is greater than is equal to the second included angle α2 of the second recess structure 4121.

The first included angle α1 is set to 20° to 60°, and the second included angle α2 is set to 0° to 60°. Optionally, the first included angle α1 is set to a different parameter such as 30°, 40°, 45°, 50°, and 55°, and the second included angle α2 is set to 10°, 15°, 20°, 30°, 35°, 40°, 45°, 50°, and 55°. For example, the first included angle α1 is set to 50°, the second included angle α2 is set to 30°, 40°, or 15°. The above parameter can be set correspondingly to achieve different recess structure having better light effect and achieve needs for different types of the display panels.

Also, the first height h1 is set to 0.1 um to 1 um, and the second height h2 is set to 0.1 um to 1 um. In particular, the first height h1 is set to 1 um, and the second height h2 is set to 0.5 um. The first width W1 is set to 1 um to 5 um, and the second width W2 is set to 1 um to 5 um. Optionally, the first width W1 is set to 4 um, and the second width W2 is set to 4 um, or 3 um. Alternatively, the widths are set according to a specific product, and no repeated description is here.

In the embodiment of the present application, to further enhance the display effect in the first display region and the second display region, it should be kept that the first height h1 and the second height h2 are set to have the same height. Namely, h1=h2. Also, the first width W1 is the same as the second width W2. Namely, W1=W2. At this time, the first included angle α1 is greater than the second included angle α2. Namely: h1=h2, W1=W2, α1>α2. At this time, the first display region 16 can emit more light 1 at a small angle under a large viewing angle, while ensuring the emission effect of light 2 within the second display region 17. Due to different recess structures causing different effects on light, the present application can accelerate brightness attenuation at a large angle in the first display region through the different recess structures mentioned above and reduce the brightness difference at a large angle in the second display region, thereby ensuring the consistency of the display panel.

In the embodiment of the present application, when it is guaranteed that the first width W1 is the same as the second width W2, the first height h1 can be greater than or equal to the second height h2, and/or, the first included angle α1 can be greater than or equal to the second included angle α2.

When the first width W1 is less than second width, the first height h1 can be greater than the second height h2, and/or, the first included angle can be equal to the second included angle.

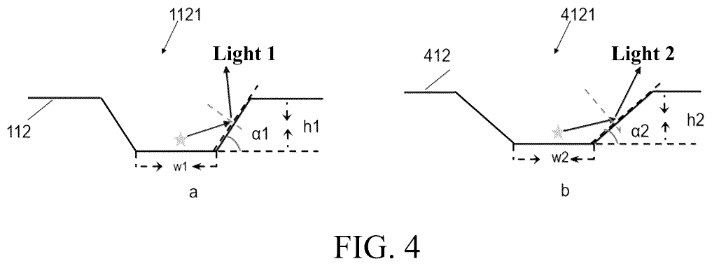

Furthermore, with reference to FIG. 4, FIG. 4 is a simplified schematic view of the second recess structure provided by the embodiment of the present application. In combination the shape of the recess structure in FIG. 3, in the embodiment of the present application, each parameter in FIG. 3 is changed. In particular, the first width W1 of the first recess structure 1121 is the same as the second width W2 of the second recess structure 4121, and the first included angle α1 of the first recess structure 1121 is the same as the second included angle α2 of the second recess structure. Also, the first height h1 of the first recess structure 1121 is greater than the second height h2 of the second recess structure. Namely, α1=α2, W1=W2, and h1>h2. At this time, a depth of the recess structure of the first recess structure 1121 in the first display region is greater than a depth of the second recess structure in the second display region.

When light inside the display panel propagates, light 1 in the light transmitting region propagates to the sidewall of the first recess structure 1121, and light 2 in the display region propagates to the sidewall of the second recess structure 4121. At the sidewall, both light 1 and light 2 are reflected again, as shown in the light path effect diagram of FIG. 4. In the embodiment of the present application, there is a difference in the width of the recess structures and the included angle between the sidewalls in the first display region and the second display region. Therefore, after light reflecting off the sidewall of the first recess structure 1121, the light is more directed towards the central axis line of the light transmitting region, meaning that the reflected light 1 is more concentrated towards the center of the region. In contrast, in the normal display region, because the second included angle α is smaller, after light 2 is reflected, the reflected light is deflected more towards the sides. That is, the amount of light reflected towards the center of the second pixel aperture is less than the amount of light reflected towards the center of the first pixel aperture in the first display region. This results in greater brightness attenuation at a larger angle compared to a smaller angle, ensuring that after brightness attenuation, the first display region and the second display region have consistent brightness, thereby guaranteeing a uniform user experience.

In the embodiment of the present application, when setting the height of the first recess structure and the second recess structure, their height does not exceed three-quarters of the corresponding second planarization layer's thickness. This ensures the planarization effect of the planarization layer and guarantees the reliability of the display panel.

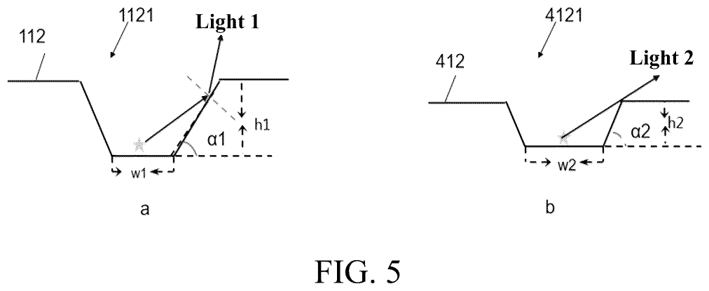

With reference to FIG. 5, FIG. 5 is a simplified schematic view of a third recess structure provided by the embodiment of the present application. In combination with structures in FIG. 3 and FIG. 4, in the embodiment of the present application, each parameter of the first recess structure and the second recess structure are improved to increase brightness consistency between the first display region and the second display region. In particular, the first width W1 of the first recess structure 1121 is less than the second width W2 of the second recess structure 4121, and the first height h1 of the first recess structure 1121 is greater than the second height h2 of the second recess structure 4121. Namely, W1<W2, h1>h2, α1=α2.

At this time, when light 1 acts within the first recess structure 1121, it is reflected by the sidewall of the first recess structure 1121. Similarly, light 2 is reflected by the sidewall of the second recess structure 4121. After reflection, light 1 is more aligned with the central axis line of the first pixel aperture in the first display region, whereas light 2 is farther from the central axis line of the second pixel aperture in the second display region. This causes more light 1 to be emitted from the center of the first display region, while light at the edge of the first display region is relatively less. Consequently, when observing the first display region and the second display region at a large viewing angle, the brightness attenuation of the first display region at a large angle will increase more rapidly, thereby matching the brightness attenuation of the second display region at a small angle. This results in consistent display brightness across the two different regions and improves the display effect of the display panel.

Also, because a plurality of different recess structures are arranged within the corresponding pixel aperture region, in one aspect, the sidewalls of the recess structures can interact with the light within the display panel, thereby ensuring that the first display region and the second display region have consistent display brightness. Additionally, after the light passes through the recess structure, it can further enhance the light-emitting rate within the display panel, thereby effectively improving the consistency of brightness across different regions.

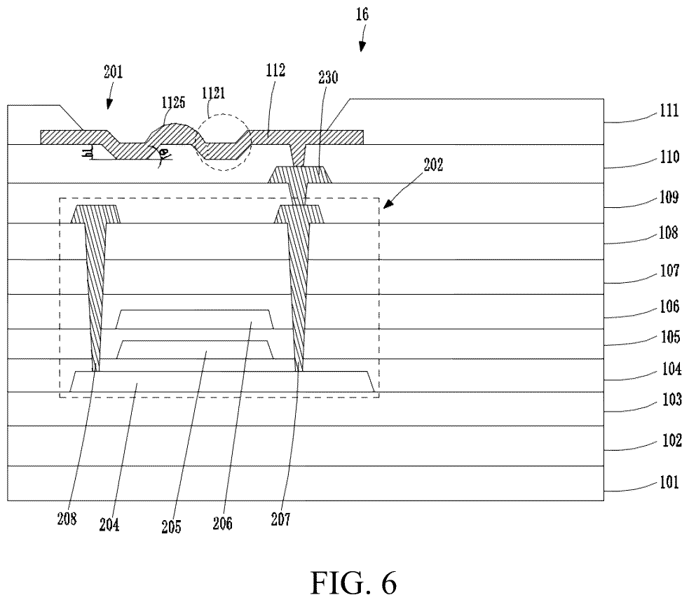

Furthermore, with reference to FIG. 6, FIG. 6 is a schematic structural view of film layers corresponding to a first display region in the display panel provided by the embodiment of the present application. In combination with the film layer structure in FIG. 2A, in the embodiment of the present application, when disposing the first pixel aperture 201 in the light transmitting region, the size of the first pixel aperture 201 can be configured according to product requirements. Additionally, the aperture area of the first pixel aperture 201 can be larger than the aperture area of the second pixel aperture within the display region. This allows more light to be emitted from the first pixel aperture 201.

Furthermore, a projection area of the first electrode 112 is greater than an area of the first pixel aperture, and a projection area of the second electrode is also greater than an area of the second pixel aperture. the projection area can be an orthographic projection area of the first electrode or the second electrode on the array substrate. Also, in the first pixel aperture 201, at least one the first recess structure 1121 can be disposed. Preferably, the first recess structure 1121 can be set as an even number, such as at least two, or set as four first recess structures, etc. Also, compared to the second display region, the area of the patterned region of the first electrode 112 corresponding to the first display region 16 can be greater than the area of the patterned region of the second electrode, thereby ensuring that the quantity of the first recess structure 1121 is greater than the quantity of the second recess structure. This effectively ensures the impact of the recess structure within the first display region on the light effect.

Furthermore, when disposing the pattern electrodes corresponding to the display region and the light transmitting region, the recess structures within the pattern electrodes in the same region can all be configured to have the same structure, such as setting the surface structure of the recess to have the same undulation. This ensures the consistency of the effect on light. Optionally, according to the aperture area of the light transmitting region, the width of the first recess structure in the central region of the light transmitting region can be set to be less than the width of the first recess structure at the edge region. This further enhances the light quantity in the central region to improve the attenuation extent and ensure consistency of brightness. Optionally, the arrangement of the above first recess structure can also be set according to the type of the actual product, which will not be elaborated here.

Furthermore, the first electrode can further comprise a plurality of first micro-bosses 1125. Similarly, the second electrode may further comprise a plurality of second micro-bosses. In FIG. 6, only the first micro-bosses 1125 within the light transmitting region are schematically shown. The second micro-bosses within the display region can be arranged by referring to the first micro-bosses. To ensure the effect of micro-bosses on light, the first micro-bosses 1125 and second micro-bosses can both be designed as arc-shaped protrusions or spherical protrusions. Such design effectively improves the light emitting rate of the display panel through the arc-shaped outer contour line and enhances the display effect.

In the embodiment of the present application, a quantity of the first micro-bosses can be greater than a quantity of the second micro-bosses. Also, a height of the first micro-boss can be greater than a height of the second micro-boss, thereby effectively improving the light emitting rate by coordinating the micro-bosses with the recessed structure of the recess structure and ensuring consistency in brightness between the first display region and the second display region.

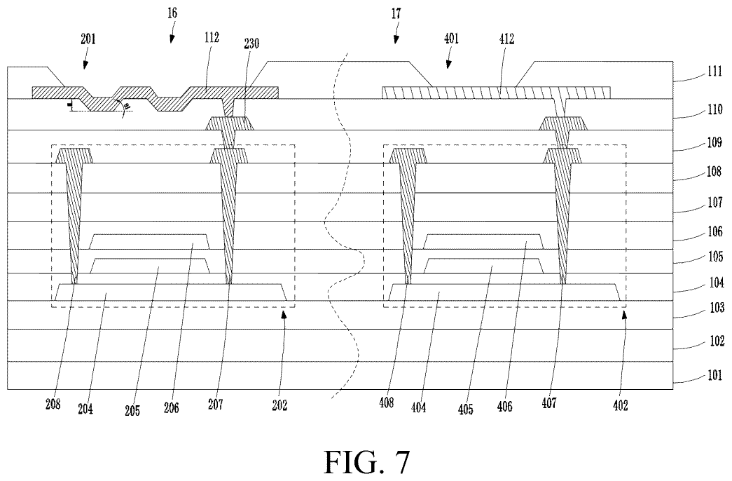

Furthermore, with reference to FIG. 7, FIG. 7 is a schematic structural view of film layers of another display panel provided by the embodiment of the present application. In conjunction with the film layer structure in FIG. 1A to FIG. 6, in the embodiment of the present application, the first display region does not have pixel wirings, which results in the corresponding light having a slower rate of brightness attenuation at large viewing angles, while the brightness attenuation in the second display region at large viewing angles is faster. According to the above attenuation pattern, in the embodiment of the present application, it is also possible to set only the corresponding electrode in the first display region.

In particular, the first electrode 112 in the first display region comprises a recess structure. When the second electrode 412 is being correspondingly disposed in the second display region, the second electrode 412 is set as horizontal film layer structure. At this time, a top surface of the second electrode 412 is a flat plane, and the flat plane is parallel to a top surface of the second planarization layer 110. As such, when light is in the first display region, it can be affected by the recess structure. Through the recess structure, this allows the light to attenuate more quickly at a large viewing angle. The light in the second display region will be directly reflected by the surface of the second electrode 412, ensuring that the light corresponding to both the first display region and the second display region has the same attenuation extent, thereby guaranteeing consistent light-emitting brightness across the display panel.

In the embodiment of the present application, the thickness of the first electrode 112 can be the same as the thickness of the second electrode 412, or according to demands, the two pattern electrodes are set to have different thicknesses to fulfill the demands of different products. Furthermore, an area of the first electrode 112 is less than an area of the second electrode 412, and in a unit area, a quantity of the first electrodes 112 is equal to a quantity of the second electrodes 412, thereby guaranteeing two different display regions having the same display brightness effect. Alternatively, according to the needs of different products, the quantity of the above-mentioned first electrode 112 and second electrode 412 can be adjusted. For example, the area of the first electrode 112 can be made larger than the area of the second electrode 412, and the quantity of the first electrode 112 per unit area can be less than the quantity of the second electrode 412, in order to meet different display requirements.

Furthermore, the display panel further comprises a connection electrode 230, and the connection electrode 230 is disposed between the first planarization layer 109 and the second planarization layer 110. A via hole is defined in a location corresponding to the connection electrode 230. By the via hole and the connection electrode 230, the first electrode 112 is electrically connected to the connection electrode 230 and is electrically connected to the first drain electrode 207 of the first thin film transistor. The second electrode 412 is electrically connected to the connection electrode 230 and is electrically connected to the second drain electrode 407 of the second thin film transistor. Therefore, driving signals are provided by corresponding thin film transistors to different pattern electrodes.

In the embodiment of the present application, the first electrode 112 and the second electrode 412 are anodes, and material of the anodes can be selected from metal material usually used in the conventional display panel, such as Ag. On the anode, a hole injection layer, a hole transport layer, a light emitting layer, an electron transport layer, an electron injection layer, a cathode, and an encapsulation are sequentially stacked. Finally, the display panel and the display device provided by the embodiment of the present application are formed. When the display panel and the display device work normally, light emitted from the light-emitting layer will be further affected by the anodes of different patterned structures, thereby effectively ensuring the brightness attenuation and light-emitting efficiency of the light-transmitting region and the display region, while also effectively improving the consistency of display brightness within the two different regions.

Furthermore, the embodiment of the present application further provides a display device. The display device the display panel provided by the above embodiment. When the display panel emits light and displays, the display region and the light transmitting region, observed from different viewing angles, have consistent light emitting brightness, thereby effectively guaranteeing the display effect of the full screen display panel and improving the overall performance of the device.

In the embodiment of the present application, the display panel and the corresponding display device can be a cell phone, computer, electronic paper, monitor, laptop, digital photo frame, or any product or component with display and camera functions. The specific type is not specifically limited.

The display panel and the display device provided by the present invention embodiment are described in detail as above. In the specification, the specific examples are used to explain the principle and embodiment of the present application. The above description of the embodiments is only used to help understand the method of the present application and its spiritual idea. Although the preferred embodiments of the present invention have been disclosed as above, the aforementioned preferred embodiments are not used to limit the present invention. The person of ordinary skill in the art may make various changes and modifications without departing from the spirit and scope of the present invention. Therefore, the scope of protection of the present invention is defined by the scope of the claims.

1. A display panel, comprising: a first display region and a second display region, wherein a light transmittance of the first display region is greater than a light transmittance of the second display region, and the display panel comprises:
an array substrate;
a first electrode layer disposed on a side of the array substrate, wherein the first electrode layer comprises a plurality of first electrodes disposed in the first display region and a plurality of second electrodes disposed in the second display region;
a pixel definition layer disposed on a side of the first electrode layer away from the array substrate, wherein the pixel definition layer comprises a plurality of pixel apertures, and the pixel apertures are disposed to correspond to the first electrodes or the second electrodes;
a light emitting layer disposed on a side of the pixel definition layer away from the array substrate; and
a second electrode layer disposed on a side of the light emitting layer away from the array substrate;
wherein the first electrodes comprises a first recess structure, a projection area of the first electrode on the array substrate is greater than an area of the first pixel aperture, and a projection area of the second electrode on the array substrate is greater than an area of the second pixel aperture.

2. The display panel according to claim 1, wherein the display panel further comprises:
a touch layer disposed on a side of the second electrode layer away from the array substrate, wherein the touch layer comprises a first aperture disposed to correspond to the first display region;
the second electrode comprises a second recess structure, and a size of at least a part of the second recess structure is different from a size of at least a part of the first recess structure.

3. The display panel according to claim 2, wherein
a first included angle is defined between a plane corresponding to a bottom portion of the first recess structure and a sidewall of the first recess structure, a second included angle is defined between a plane corresponding to a bottom portion of the second recess structure and a sidewall of the second recess structure, and each of the first included angle and the second included angle is less or equal to 90°;
the first recess structure comprises a first height, and the second recess structure comprises a second height;
the bottom portion of the first recess structure comprises a first width, the bottom portion of the second recess structure comprises a second width; in three correspondence relations formed by the first width to the second width, the first included angle to the second included angle, and the first height to the second height, and parameter values in at least one of the correspondence relations are not the same.

4. The display panel according to claim 3, wherein the first width is the same as the second width; and
the first width is set to 1 um to 5 um.

5. The display panel according to claim 4, wherein the first height is greater than or equal to the second height, and/or, the first included angle is greater than or equal to the second included angle.

6. The display panel according to claim 3, wherein
the first width is less than the second width, the first height is greater than the second height, and/or, the first included angle is equal to the second included angle.

7. The display panel according to claim 3, wherein the first included angle is set to 20° to 60°, and the second included angle is set to 0° to 60°.

8. The display panel according to claim 2, wherein a quantity of the first recess structure is greater than a quantity of the second recess structure.

9. A display panel, comprising: a first display region and a second display region, wherein a light transmittance of the first display region is greater than a light transmittance of the second display region, and the display panel comprises:
an array substrate;
a first electrode layer disposed on a side of the array substrate, wherein the first electrode layer comprises a plurality of first electrodes disposed in the first display region and a plurality of second electrodes disposed in the second display region;
a pixel definition layer disposed on a side of the first electrode layer away from the array substrate, wherein the pixel definition layer comprises a plurality of pixel apertures, and the pixel apertures are disposed to correspond to the first electrodes or the second electrodes;
a light emitting layer disposed on a side of the pixel definition layer away from the array substrate; and
a second electrode layer disposed on a side of the light emitting layer away from the array substrate;
wherein the first electrodes comprises a first recess structure.

10. The display panel according to claim 9, wherein the display panel further comprises:
a touch layer disposed on a side of the second electrode layer away from the array substrate, wherein the touch layer comprises a first aperture disposed to correspond to the first display region;
the second electrode comprises a second recess structure, and a size of at least a part of the second recess structure is different from a size of at least a part of the first recess structure.

11. The display panel according to claim 10, wherein
a first included angle is defined between a plane corresponding to a bottom portion of the first recess structure and a sidewall of the first recess structure, a second included angle is defined between a plane corresponding to a bottom portion of the second recess structure and a sidewall of the second recess structure, and each of the first included angle and the second included angle is less or equal to 90°;
the first recess structure comprises a first height, and the second recess structure comprises a second height;
the bottom portion of the first recess structure comprises a first width, the bottom portion of the second recess structure comprises a second width; in three correspondence relations formed by the first width to the second width, the first included angle to the second included angle, and the first height to the second height, and parameter values in at least one of the correspondence relations are not the same.

12. The display panel according to claim 11, wherein the first width is the same as the second width; and
the first width is set to 1 um to 5 um.

13. The display panel according to claim 12, wherein the first height is greater than or equal to the second height, and/or, the first included angle is greater than or equal to the second included angle.

14. The display panel according to claim 11, wherein the first width is less than the second width, the first height is greater than the second height, and/or, the first included angle is equal to the second included angle.

15. The display panel according to claim 11, wherein the first included angle is set to 20° to 60°, and the second included angle is set to 0° to 60°.

16. The display panel according to claim 10, wherein a quantity of the first recess structure is greater than a quantity of the second recess structure.

17. The display panel according to claim 9, wherein the first recess structure is arranged symmetrically relative to a central axis line of a corresponding one of the pixel apertures, and the first recess structure is arranged symmetrically relative to the central axis line of a corresponding one of the pixel apertures.

18. The display panel according to claim 9, wherein the display panel further comprises:
a planarization layer disposed between the array substrate and the first electrode layer, wherein the planarization layer comprises: a third recess structure disposed to correspond to the first recess structure and a fourth recess structure disposed to correspond to the second recess structure, and a depth of each of the third recess structure of the fourth recess structure is less than or equal to a thickness of the planarization layer.

19. The display panel according to claim 9, wherein an area of the first electrode is less than an area of the second electrode, and a quantity of the first electrodes in a unit area is equal to a quantity of the second electrodes;
or
an area of the first electrode is greater than an area of the second electrode, and a quantity of the first electrodes in a unit area is less than a quantity of the second electrodes.

20. A display device, comprising a display panel, and the display panel comprising: a first display region and a second display region, wherein a light transmittance of the first display region is greater than a light transmittance of the second display region, and the display panel comprises:
an array substrate;
a first electrode layer disposed on a side of the array substrate, wherein the first electrode layer comprises a plurality of first electrodes disposed in the first display region and a plurality of second electrodes disposed in the second display region;
a pixel definition layer disposed on a side of the first electrode layer away from the array substrate, wherein the pixel definition layer comprises a plurality of pixel apertures, and the pixel apertures are disposed to correspond to the first electrodes or the second electrodes;
a light emitting layer disposed on a side of the pixel definition layer away from the array substrate; and
a second electrode layer disposed on a side of the light emitting layer away from the array substrate;
wherein the first electrodes comprises a first recess structure.
